(19) United States
(12) Patent Application Publication
(10) Pub. No.: US 2005/0257746 A1
(43) Pub. Date: Nov. 24, 2005

(54) Clamp member, film deposition apparatus, film deposition method, and semiconductor device manufacturing method

(76) Inventors: Kenji Shirakawa, Hyogo (JP); Nobuhiro Nishizaki, Hyogo (JP); Kohichi Sekiya, Hyogo (JP); Kazuo Iwami, Hyogo (JP); Masato Toyota, Hyogo (JP)

Correspondence Address: MCDERMOTT WILL & EMERY LLP, 600 13TH STREET, N.W., WASHINGTON, DC, 20005-3096, US

(21) Appl. No.: 11/133,452

(22) Filed: May 20, 2005

(30) Foreign Application Priority Data
May 21, 2004 (JP) 2004-151953(P)

(51) Int. Cl. C23C 16/00

(52) U.S. Cl. 118/728; 204/192.1

(57) ABSTRACT

A clamp member capable of reliably releasing sticking to a substrate with a simple structure, a film deposition apparatus and method, and a semiconductor device manufacturing method using the clamp member are provided. A clamp ring includes an inner flange portion, a rotating shaft arranged at the inner flange portion, and a rotating member. The rotating member is rotatable about the rotating shaft, and has front and rear end portions. The rotating member is arranged such that the front end portion is positioned to face a part of the wafer with a space therebetween when the inner flange portion is holding the wafer. When the rear end portion is pressed against the inner flange portion, the rotating member rotates about the rotating shaft, and thus, the front end portion can press the part of the wafer in a direction away from the inner flange portion.

### BACKGROUND OF THE INVENTION

1. Field of the Invention

The present invention relates to a clamp member, a film deposition apparatus, a film deposition method, and a manufacturing method of a semiconductor device. More particularly, the present invention relates to a clamp member for holding a substrate during a film deposition step, a film deposition apparatus, a film deposition method, and a manufacturing method of a semiconductor device.

2. Description of the Background Art

Conventionally, a clamp member for holding a substrate (wafer) in a film deposition apparatus is known (see, e.g., Japanese Patent Laying-Open No. 61-291346).

Japanese Patent Laying-Open No. 61-291346 discloses a clamp member which includes a wafer-mounting circular table rotatable from a horizontal state to a vertical state via an arm, a driving platform having a central axis corresponding to that of the wafer-mounting table in the horizontal state, at least a pair of opposed wafer-holding means in the form of claws that are arranged in the vicinity of the rim of the wafer-mounting table and laid down inward when the rotating arm moves from the horizontal state to the vertical state, and a guide for opening the claws when the rotating arm takes a horizontal position.

The clamp member described above is relatively complicated in structure, since film deposition is carried out with the substrate set in the vertical state. Further, in the above clamp member, the claws are moved to beneath the guide after the film deposition so as to release the holding of the substrate. Since any active manipulation such as pressing the substrate is not conducted to release the sticking of the substrate to the claws caused by a film formed over the surfaces of the substrate and the claws, there may arise a problem that the claws stuck to the substrate are not separated properly.

### SUMMARY OF THE INVENTION

An object of the present invention is to provide a clamp member capable of reliably releasing sticking to a substrate with a simple structure, and a film deposition apparatus, a film deposition method and a semiconductor device manufacturing method using the clamp member.

A clamp member according to the present invention holds a substrate when the substrate is subjected to processing. The clamp member includes a holding portion for holding the substrate, a rotating shaft arranged at the holding portion, and a rotating member. The rotating member is rotatable about the rotating shaft, and has one end and another end. The rotating member is arranged such that the one end is positioned to face a part of the substrate with a space therebetween when the holding portion is holding the substrate. In the state where the holding portion is holding the substrate, when the other end of the rotating member is pressed against the holding portion to cause the rotating member to rotate about the rotating shaft, the one end of the rotating member can press the part of the substrate in a direction moving away from the holding portion.

As described above, according to the present invention, one end of the rotating member presses a part of the substrate to ensure separation of the clamp member from the substrate. This can reduce the probability of occurrence of the problem that the clamp member and the substrate cannot be separated from each other in a processing apparatus provided with the clamp member.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view of a sputtering apparatus having a clamp ring according to the present invention.

FIGS. 2 and 3 are partial cross sectional views of the clamp ring in the sputtering apparatus shown in FIG. 1.

FIG. 4 is a flowchart illustrating a sputtering method using the sputtering apparatus shown in FIGS. 1-3.

FIG. 5 is a flowchart illustrating the content of the wafer taking-out step shown in FIG. 4.

FIG. 6 is a partial cross sectional view of the clamp ring, showing the state where the clamp ring comes into contact with the wafer in the step of making the clamp ring and the wafer contact each other shown in FIG. 4.

FIG. 7 is a partial cross sectional view of the clamp ring illustrating the operation of the clamp ring shown in FIG. 6.

FIG. 8 is a partial cross sectional view of the clamp ring illustrating the wafer taking-out step shown in FIG. 4.

FIG. 9 is a partial cross sectional view of a first modification of the clamp ring arranged in a sputtering apparatus according to the present invention.

FIG. 10 is a schematic plan view illustrating a second modification of the clamp ring according to the present invention.

FIG. 11 is a partial cross sectional view of a clamp ring for comparison, illustrating the effect of the clamp ring according to the present invention.

### DESCRIPTION OF THE PREFERRED EMBODIMENTS

Hereinafter, embodiments of the present invention will be described with reference to the drawings. Throughout the drawings, the same or corresponding portions have the same reference characters allotted, and description thereof will not be repeated.

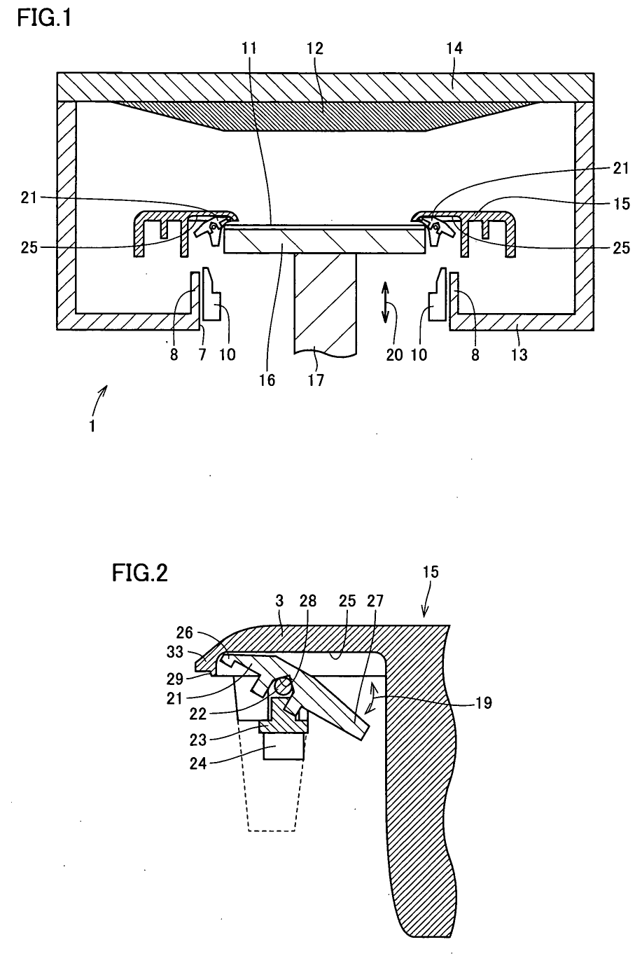

Referring to FIGS. 1-3, a clamp ring and a sputtering apparatus according to the present invention will be described. As shown in FIG. 1, the sputtering apparatus 1 representing a manufacturing apparatus of a semiconductor device according to the present invention includes a chamber formed of a lower shield body 13 and a lid member 14 arranged to close an opening formed on the top of lower shield body 13. A stage 16 is arranged within the chamber, which can move up and down in the directions shown by an arrow 20. Stage 16 is mounted on a base portion 17. A wafer 11 of silicon to be processed is mounted on stage 16.

A clamp ring 1 5 is arranged to press and secure the rim of wafer 11. Further, a target member 12 for sputtering is arranged on a position of an inner surface of lid member 14 facing stage 16. A material for target member 12 may be selected as appropriate in accordance with the material of the film to be formed on a surface of wafer 11. For example, aluminum or aluminum alloy may be used for target member 12. A lifter 10 for use in transporting wafer 11 is arranged to face an opening 7 of lower shield body 13 constituting the chamber. Clamp ring 15 has a flange portion on the inner-peripheral side (hereinafter, referred to as “inner flange portion”) 3. Provided at an end of inner flange portion 3 to face wafer 11 (on the under surface facing wafer 11) are a clamp portion 29 for pressing wafer 11, and a rotating member 21 arranged inside a concave portion 25 formed on the outer side of clamp portion 29.

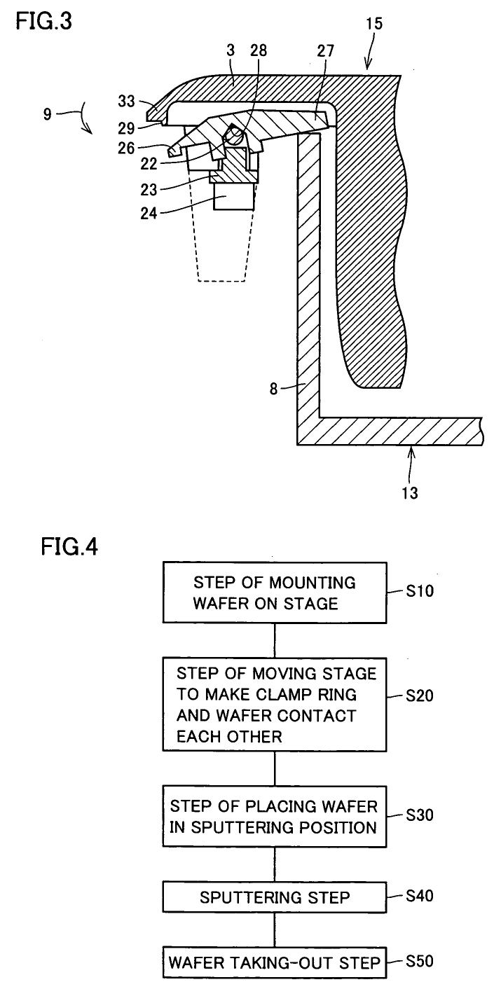

Rotating member 21 is preferably formed of the same material as clamp ring 15. For example, rotating member 21 and clamp ring 15 may be formed of stainless steel. Alternatively, another arbitrary material having a relatively small coefficient of linear expansion may be used for rotating member 21. Rotating member 21 has a front end portion 26, a rear end portion 27 located on the opposite side from front end portion 26, and a groove 28 formed between front end portion 26 and rear end portion 27. Groove 28 mates with a rotating shaft 22. A pressing plate 23 presses and secures rotating shaft 22 against clamp ring 15. Pressing plate 23 is fixed to clamp ring 15 by a screw 24. Rotating member 21 is rotatable about rotating shaft 22 in the directions shown by an arrow 19. Rotating member 21 has a center of gravity offset outward from groove 28 (to the side of rear end portion 27) such that, when no external stress is applied, its rear end portion 27 is lowered as shown in FIG. 2 (to attain the state of FIG. 2). When clamp ring 15 is mounted on lower shield body 13 constituting the chamber, a sidewall 8 of lower shield body 13 presses rear end portion 27 of rotating member 21. As such, as shown in FIG. 3, rear end portion 27 of rotating member 21 is lifted, and front end portion 26 of rotating member 21 moves downward (in the direction shown by an arrow 9). As a result, front end portion 26 of rotating member 21 can be moved to protrude downward from the level of the bottom end of clamp portion 29.

Further, on the inner peripheral side of clamp ring 15, a convex portion 33 is formed to extend (protrude) toward the center of wafer 11 from clamp portion 29 coming into contact with the surface of wafer 11. Provision of convex portion 33 can reduce the possibility that, during sputtering of wafer 11, atoms sputtered from target member 12 reach the contact position between clamp portion 29 and wafer 11 to form a film even on the surfaces of clamp portion 29 and rotating member 21. This in turn reduces the possibility that wafer 11 and clamp portion 29 are stuck to each other by the film formed by sputtering to extend from the surface of wafer 11 to the surface of clamp portion 29 (on the contact portion between wafer 11 and clamp portion 29).

A sputtering method using sputtering apparatus 1 shown in FIGS. 1-3 will now be described with reference to FIGS. 4-8.

In the sputtering method using the sputtering apparatus shown in FIG. 1, firstly, the step (S10) of mounting a wafer on a stage is carried out, as shown in FIG. 4. At this time, in sputtering apparatus 1 of FIG. 1, stage 16 is arranged at a position lower than opening 7 of lower shield body 13 (i.e., located outside the lower shield body 13). A wafer-transporting robot places wafer 11 to be processed (see FIG. 1) on a lifter 10. Next, stage 16 is moved upward, and wafer 11 having been held by lifter 10 is mounted on an upper surface of stage 16. At this time, clamp ring 15 is in the state (as shown in FIG. 3) mounted on sidewall 8 of lower shield body 13.

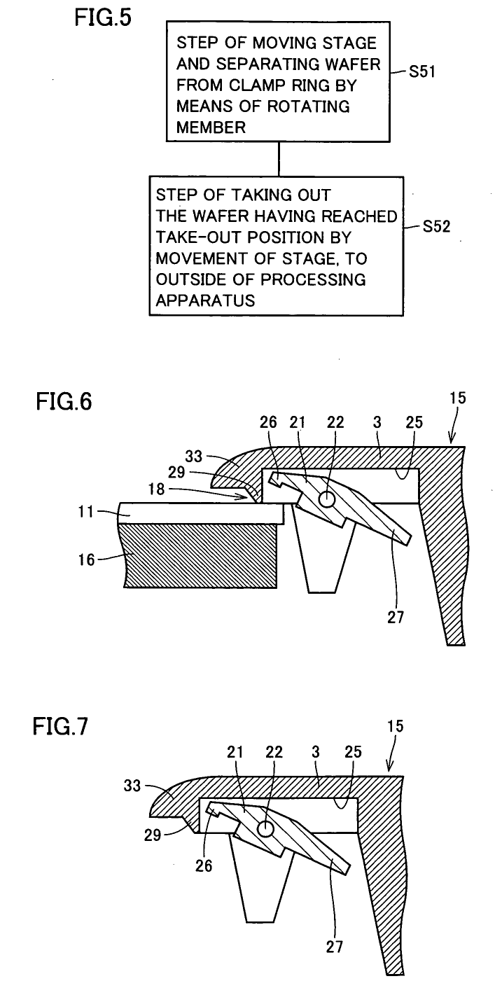

Next, the step (S20) of moving stage 16 further upward (to the inside of the chamber) to make the wafer and the clamp ring contact each other is carried out. Specifically, in this step (S20), stage 16 is further raised, so that clamp portion 29 of clamp ring 15 comes into contact with an end portion of wafer 11 arranged on stage 16, as shown in FIG. 6.

It is noted that clamp ring 15 is initially rested on sidewall 8 of lower shield body 13, as shown in FIG. 3, and front end portion 26 of rotating member 21 is in the lower level than (or protruding downward from) clamp portion 29 of clamp ring 15, again as shown in FIG. 3. Thus, it is in fact the front end portion 26 of rotating member 21 that first comes into contact with the end of wafer 11 as it is raised along with ascent of stage 16. As stage 16 is further moved upward, the end of wafer 11 presses front end portion 26 of rotating member 21, so that rotating member 21 rotates about rotating shaft 22 to raise front end portion 26. At the same time, clamp ring 15 is raised upward gradually while being pressed by wafer 11.

Wafer 11 is further raised in accordance with ascent of stage 16, and the end of wafer 11 comes into contact with clamp portion 29 of clamp ring 15. As stage 16 is further moved upward, clamp ring 15 is lifted from sidewall 8 of lower shield body 13, and rear end portion 27 of rotating member 21 comes apart from the upper end of sidewall 8 of lower shield body 13. As a result, as shown in FIG. 6, front end portion 26 of rotating member 21 provided at clamp ring 15 comes to face the end of wafer 11 with a space therebetween, i.e., front end portion 26 comes apart from the end of wafer 11. This is because rotating member 21 has its center of gravity offset from rotating shaft 22 to the side of rear end portion 27, as shown in FIG. 7, and thus, when no external force is applied, rotating member 21 has its front end portion 26 positioned at an upper level (closer to the upper surface of clamp ring 15) than rear end portion 27.

Next, the step (S30) of placing the wafer in a sputtering position is carried out. Specifically, stage 16 is further moved upward to arrange wafer 11 at a prescribed position (e.g., the position shown in FIG. 1) where wafer 11 is subjected to the sputtering process.

Subsequently, the sputtering step (S40) is carried out. In the sputtering step (S40), for example, ions are impinged on target member 12 to sputter the particles (atoms) of the material of target member 12. The particles (atoms) thus sputtered are accumulated on the surface of wafer 11, so that a film is formed on the surface of wafer 11. For example, when aluminum is used for the material of target member 12, the aluminum particles sputtered from target member 12 accumulate on the surface of wafer 11 to form an aluminum film. In the sputtering step (S40), any conventional sputtering method can be employed.

After completion of the sputtering step (S40) for depositing the film of a prescribed thickness on the surface of wafer 11 as described above, the step (S50) of taking wafer 11 out of sputtering apparatus 1 is carried out. Specifically, stage 16 mounting wafer 11 having undergone the film depositing process thereon is moved toward the outside of the chamber (from the inside to the outside of the chamber via opening 7 in FIG. 1).

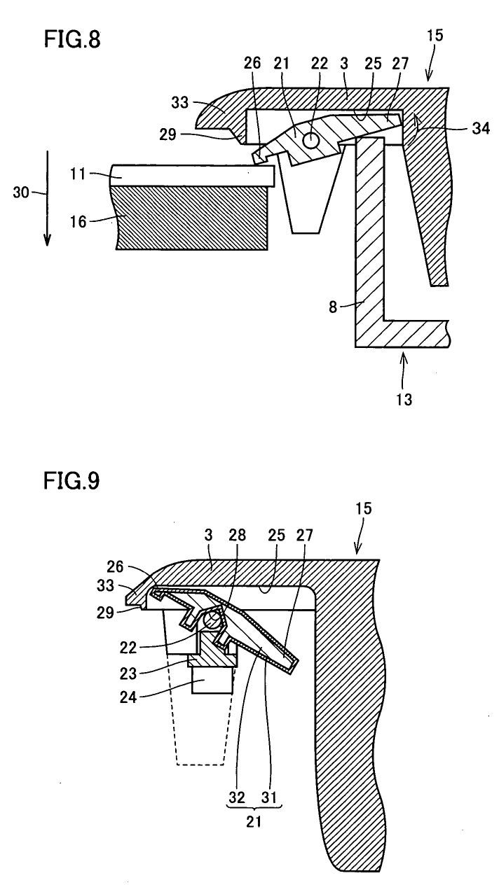

The wafer taking-out step.(S50) will now be described in more detail. In the wafer taking-out step (S50), as shown in FIG. 5, the step (S51) of moving stage 16 and separating wafer 11 from clamp ring 15 by means of rotating member 21 is carried out. Specifically, as shown in FIG. 8, stage 16 is lowered together with clamp ring 15 in the direction shown by an arrow 30, so that the upper end portion of sidewall 8 of lower shield body 13 comes to press rear end portion 27 of rotating member 21 provided at clamp ring 15. As a result, rotating member 21 rotates about rotating shaft 22 in the direction shown by an arrow 34 (that is, rotating member 21 acts as a lever, with rotating shaft 22 being a point of support, rear end portion 27 being a power point and front end portion 26 being a point of application). Pressing the end of wafer 11 with front end portion 26 of rotating member 21 ensures separation of clamp portion 29 of clamp ring 15 from wafer 11.

In the case as shown in FIG. 11 where a clamp ring 115 not provided with rotating member 21 (see FIG. 8) as in the present invention is used to press and secure a wafer 111 mounted on a stage 116, a film deposited on wafer 111 in the sputtering step may extend to a contact portion 118 between clamp ring 115 and wafer 111. In this case, the film thus formed connects clamp ring 115 with wafer 111, making it difficult to separate clamp ring 115 from wafer 111 by simply lowering stage 116. In contrast, according to the present invention, front end portion 26 of rotating member 21 can press the end of wafer 11, as shown in FIG. 8, ensuring separation of clamp ring 15 from wafer 11.

Next, as the wafer taking-out step (S50), the step (S52) of taking out wafer 11 having reached a take-out position by movement of stage 16, to the outside of the processing apparatus (sputtering apparatus 1) is carried out. Specifically, stage 16 mounting wafer 11 that has been separated from clamp ring 15 thereon is moved to a prescribed position (take-out position) outside the chamber. As a result, wafer 11 having undergone the film deposition process is mounted on the lifter, and a device for transporting the wafer (a wafer-transporting robot or the like) is used to take out wafer 11 having undergone the film deposition process to the outside of sputtering apparatus As such, the sputtering step using sputtering apparatus 1 shown in FIGS. 1-3 is carried out.

Hereinafter, a first modification of the clamp ring incorporated in a sputtering apparatus according to the present invention will be described with reference to FIG. 9.

As shown in FIG. 9, a clamp ring 15 of the first modification basically has a structure similar to that of clamp ring 15 shown in FIG. 1-3, except for the configuration of rotating member 21. More specifically, rotating member 21 provided at clamp ring 15 shown in FIG. 9 is formed of a base body 32 of a prescribed shape and a surface treatment layer 31 formed to cover base body 32. For this surface treatment layer 31, any surface treatment may be carried out as long as it can improve surface hardness and/or abrasion resistance. For example, surface treatment layer 31 may be a nitrided layer. In the case where a material that can be quenched, such as steel, is used as a material of rotating member 21, a layer hardened by quenching may serve as surface treatment layer 31. Further, any hardening process, including the above-described quenching, may be used to form surface treatment layer 31. Still further, a plated layer formed by plating the surface of base body 32 may also serve as surface treatment layer 31.

By using clamp ring 15 having such a structure, similar effects as in the case of using the clamp ring shown in FIGS. 1-3 can be obtained. Further, if a layer excellent in hardness and abrasion resistance is provided as surface treatment layer 31, the life of rotating member 21 can be elongated.

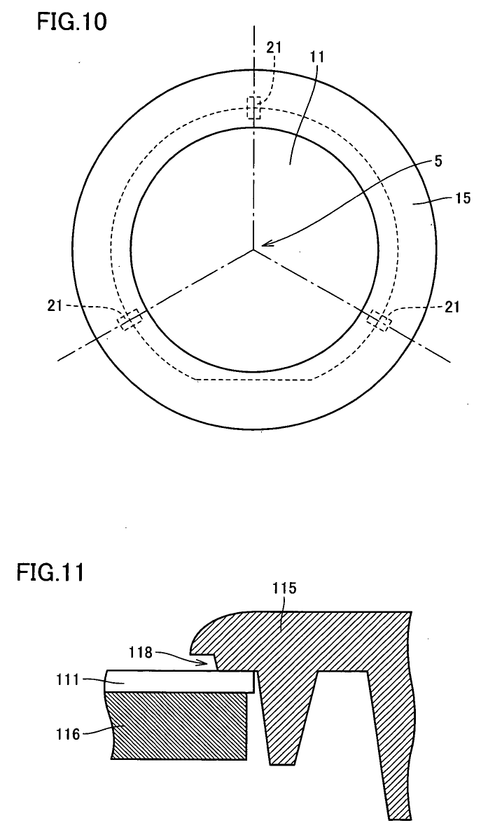

A second modification of the clamp ring according to the present invention will now be described with reference to FIG. 10.

In clamp ring 15 provided to sputtering apparatus 1 shown in FIGS. 1-3, two rotating members 21 are placed opposite to each other as seen from the center of clamp ring 15. However, the number of rotating members 21 may be three, as shown in FIG. 10, or four or more. It is also possible to provide only one rotating member 21 to clamp ring 15.

Further, in the case of providing a plurality of (for example, three) rotating members 21 to clamp ring 15, it is preferable that rotating members 21 are arranged at equal distances from each other as seen from the central point 5 of clamp ring 15, as shown in FIG. 10. With this configuration, when separating wafer 11 from clamp ring 15 by pressing the end of wafer 11 by means of front end portions 26 of rotating members 21 as shown in FIG. 8, uniform force can be applied to wafer 11. This further ensures separation of wafer 11 from clamp ring 15.

The characteristic configuration of the above-described clamp ring 15 according to the present invention can be summarized as follows. Clamp ring 15 as a clamp member according to the present invention is for holding a substrate (wafer 11) when the substrate (wafer 11) is subjected to processing. It includes inner flange portion 3 as a holding portion for holding wafer 11, rotating shaft 22 arranged at inner flange portion 3, and rotating member 21. Rotating member 21 is rotatable about rotating shaft 22, and has front end portion 26 as one end and rear end portion 27 as another end. Rotating member 21 is arranged such that, when inner flange portion 3 is holding wafer 11, front end portion 26 is positioned to face a part of wafer 11 with a space therebetween. In the state where clamp portion 29 of inner flange portion 3 is holding wafer 11, when rear end portion 27 of rotating member 21 is pressed against inner flange portion 3, rotating member 21 rotates about rotating shaft 22, and front end portion 26 can press a part (an end) of wafer 11 in a direction away from inner flange portion 3. Inner flange portion 3 of clamp ring 15 may be provided with a concave portion for receiving a part (an end) of rotating shaft 22. Rotating shaft 22 may be pressed and secured to inner flange portion 3 by means of a pressing plate 23 as a pressing member. Pressing plate 23 may be fixed to inner flange portion 3 by means of a screw 24 as a fixing member.

In this manner, by provision of a relatively simple mechanism of clamp ring 15 provided with rotating member 21, when wafer 11 pressed and held by clamp portion 29 of inner flange portion 3 is to be separated from clamp ring 15, front end portion 26 of rotating member 21 can press a part of wafer 11, ensuring separation of wafer 11 from inner flange portion 3 of clamp ring 15.

Further, in the state where inner flange portion 3 is holding wafer 11, front end portion 26 of rotating member 21 is spaced apart from a part of wafer 11 (i.e., wafer 11 and rotating member 21 are not in contact with each other), as shown in FIG. 6. Thus, even if wafer 11 held by inner flange portion 3 is subjected to processing (e.g., film deposition by sputtering), the possibility that front end portion 26 of rotating member 21 and wafer 11 are stuck to each other due to the processing (i.e., a film continuously covering the surfaces of front end portion 26 of rotating member 21 and wafer 11 connects rotating member 21 and wafer 11) can be reduced.

As such, the probability of occurrence of the problem that wafer 11 cannot be separated from clamp ring 15 after a film deposition process such as sputtering is carried out on wafer 11 held by clamp ring 15 of the present invention can be reduced. This in turn reduces the possibility that the operating rate of sputtering apparatus 1 as the processing apparatus for processing wafer 11 is lowered due to the failure of separating wafer 11 from clamp ring 15. Further, in the case where wafer 11 cannot be separated from clamp ring 15 as described above, the operation of sputtering apparatus 1 will have to be stopped and an operator will need to manually remove wafer 11 from clamp ring 15. In such a case, wafer 11 may have to be discarded depending on the surface condition or the like. By comparison, when clamp ring 15 of the present invention is used, it is possible to reduce the case where wafer 11 has to be removed manually, and as a result, the number of wafers 11 that have to be discarded can be lowered (leading to improvement in yield of wafers 11).

Further, in the case where clamp portion 29 of inner flange portion 3 is holding wafer 11, rotating member 21 is not in contact with wafer 11, as described above. Thus, even if rotating member 21 moves while wafer 11 is under film deposition processing such as sputtering, the possibility that wafer 11 vibrates due to the movement of rotating member 21 can be reduced. This in turn reduces the probability of generation of foreign particles due to the vibration of wafer 11 and, hence, the possibility of degradation in quality of processed wafer 11 (e.g., the quality of the formed film).

Clamp ring 15 described above may have a concave portion 25 formed on a surface of inner flange portion 3 facing wafer 11, and rotating member 21 may be arranged in concave portion 25 of inner flange portion 3. This can decrease the increased ratio of the area occupied by inner flange portion 3 when providing rotating member 21 to inner flange portion 3 with respect to the area occupied by inner flange portion 3 not provided with rotating member 21. As such, it is possible to incorporate clamp ring 15 of the present invention into a processing apparatus, such as sputtering apparatus 1, without a particular need to change the structure of the processing apparatus.

In clamp ring 15 described above, the material of rotating member 21 may include one selected from a group consisting of stainless alloy and materials (also referred to as “materials of low linear expansion coefficients”) each having a coefficient of linear expansion that is lower than the coefficient of linear expansion of iron. In the case where there is a need to heat wafer 11 held by clamp ring 15 when performing processing on wafer 11, the temperature of clamp ring 15 also increases. In such a case, when rotating member 21 is formed of the material as described above, rotating member 21 can stably maintain its shape even if the temperature of rotating member 21 is increased with the temperature increase of clamp ring 15 (the degree of deformation of rotating member 21 due to thermal expansion can be reduced). As a result, it is possible to reduce the probability of occurrence of a problem that deformed rotating member 21 cannot perform a normal operation (e.g., it cannot perform a rotating operation about rotating shaft 22).

As the material of low linear expansion coefficient, one having a coefficient of linear expansion lower than that of iron in the temperature range (e.g., from 20° C. to 800° C.) in which clamp ring 15 is used, for example, may be employed. For example, refractory metals such as titanium, tantalum and tungsten, platinum, carbon and others may be used as the materials of low linear expansion coefficients.

In clamp ring 15 described above, a concave portion. 33 may be formed at the surface of inner flange portion 3 along the surface of wafer 11 being held by inner flange portion 3 to protrude to the outside of the region where rotating member 21 is arranged (in the direction toward the center of wafer 11). In this case, the possibility that, when wafer 11 is subjected to sputtering or the like, contact portion 18 between clamp ring 15 and wafer 11 (see FIG. 6) or rotating member 21 of clamp ring 15 will suffer an adverse effect of the process (e.g., when film deposition processing such as sputtering is carried out, the possibility that a film is formed at the above-described contact portion 18 or on the surface of rotating member 21) can be reduced.

In clamp ring 15 described above, a surface treatment layer 31 may be formed at a surface of rotating member 21, as shown in FIG. 9. In this case, a material layer (surface treatment layer 31) made of a material different from that of the base (base body 32) of rotating member 21 can be formed at the surface of rotating member 21. When the material for surface treatment layer 31 is selected appropriately, properties of rotating member 21, such as durability, can be improved. For example, if a nitrided layer or another layer made of a material excellent in abrasion resistance is formed as surface treatment layer 31, the degree of abrasion of rotating member 21 can be reduced, and thus, the life of rotating member 21 is elongated.

In clamp ring 15 described above, in a position of rotating member 21 to be fitted with rotating shaft 22, a groove 28 may be formed to extend along rotating shaft 22 and receive rotating shaft 22 therein. A bottom of groove 28 may have a cross section of a triangular shape in a direction crossing the extending direction of rotating shaft 22. In this case, sidewalls at the bottom of groove 28 are made of flat surfaces, making it possible to readily form groove 28 upon manufacture of rotating member 21.

Sputtering apparatus 1 as a film deposition apparatus according to the present invention is provided with clamp ring 15 described above. In this case, even if clamp ring 15 and the substrate (wafer 11) are stuck to each other in the sputtering step (S40) as the film deposition process, it is readily possible to separate the substrate (wafer 11) from clamp ring 15 using rotating member 21.

A film deposition method according to the present invention includes the following steps. Firstly, the step of holding wafer 11 as the substrate using the above-described clamp member (the step of making clamp ring 15 and wafer 11 contact each other (S20)) is carried out. The step of forming a film on a surface of the held wafer 11, i.e., the film deposition step (sputtering step (S40)) is carried out. After completion of the film deposition step (sputtering step (S40)), the step of separating wafer 11 from inner flange portion 3 of clamp ring 15 by pressing the other end (rear end portion 27) of rotating member 21 of clamp ring 15 against the holding portion (inner flange portion 3) to rotate rotating member 21 about rotating shaft 22, to thereby press a part (an end) of wafer 11 by the one end (front end portion 26) of rotating member 21 (the step of separating the wafer from the clamp ring (S51)) is carried out.

In the step of separating wafer 11 from the holding portion (inner flange portion 3) of clamp ring 15, the one end (front end portion 26) of rotating member 21 can press the part of wafer 11. This ensures separation of wafer 11 from the holding portion (inner flange portion 3) of clamp ring 15. Further, when the holding portion (inner flange portion 3) is holding wafer 11, the one end (front end portion 26) of rotating member 21 is arranged at a distance from the part (the end) of wafer 11 (i.e., wafer 11 and rotating member 21 are not in contact with each other). Thus, even if wafer 11 held by the holding portion (inner flange portion 3) is subjected to the film deposition step (sputtering step (S40)), the possibility of sticking of rotating member 21 to wafer 11 because of a film formed continuously from wafer 11 to the one end (front end portion 26) of rotating member 21 during the film deposition processing (sputtering) can be reduced.

As such, the probability of occurrence of a problem that wafer 11 cannot be separated from clamp ring 15 in the step of separating the substrate (the step of separating the wafer from the clamp ring (S51)) is reduced. As a result, it is possible to reduce the possibility that the operating rate of sputtering apparatus 1 as the processing apparatus for performing processing on wafer 11 is decreased because wafer 11 cannot be separated from clamp ring 15.

If wafer 11 cannot be separated from clamp ring 15 as described above, the operation of sputtering apparatus 1 will have to be stopped and an operator will have to manually remove wafer 11 from clamp ring 15. In this case, wafer 11 may have to be discarded depending on the surface condition of the wafer 11. In contrast, when clamp ring 15 of the present invention is used, the possibility that such manual removal of wafer 11 becomes necessary is reduced, and as a result, the number of wafers 11 discarded is decreased (i.e., the yield of wafers 11 and the yield of the semiconductor devices using the wafers 11 can be improved).

When the holding portion (inner flange portion 3) is holding wafer 11, rotating member 21 is not in contact with wafer 11, as described above. Thus, even if rotating member 21 moves while wafer 11 is being subjected to the sputtering process, the possibility that wafer 11 vibrates due to the movement of rotating member 21 can be reduced. Since the probability of generation of foreign particles due to the vibration of wafer 11 can be reduced, the possibility that the quality of the film formed on wafer 11 is degraded by the foreign particles can also be reduced.

A manufacturing method of a semiconductor device according to the present invention uses the above-described film deposition method. In the film deposition step (sputtering step (S40)), sputtering is used to form the film. In this case, it is readily possible to apply the film deposition method of the present invention to the manufacturing step of a semiconductor device.

Although the present invention has been described and illustrated in detail, it is clearly understood that the same is by way of illustration and example only and is not to be taken by way of limitation, the spirit and scope of the present invention being limited only by the terms of the appended claims.

1. A clamp member for holding a substrate when said substrate is subjected to processing, comprising:
a holding portion for holding a substrate;
a rotating shaft arranged at said holding portion; and
a rotating member rotatable about said rotating shaft, the rotating member having an end and another and; wherein
said rotating member is arranged such that said one end is positioned to face a part of said substrate with a space therebetween when said holding portion is holding said substrate, and
when said other end of said rotating member is pressed against said holding portion in the state where said holding portion is holding said substrate, said rotating member rotates about said rotating shaft, and said one end can press the part of said substrate in a direction away from said holding portion.

2. The clamp member according to claim 1, wherein
a concave portion is formed at a surface of said holding portion facing said substrate, and
said rotating member is arranged in the concave portion of said holding portion.

3. The clamp member according to claim 1, wherein a material of said rotating member includes one selected from a group consisting of stainless alloy and materials each having a coefficient of linear expansion lower than a coefficient of linear expansion of iron.

4. The clamp member according to claim 1, wherein a convex portion is formed at a surface of said holding portion to extend along a surface of said substrate held by said holding portion and protrude outward from an area where said rotating member is arranged.

5. The clamp member according to claim 1, wherein a surface treatment layer is provided at a surface of said rotating member.

6. The clamp member according to claim 1, wherein
a portion of said rotating member to be fitted with said rotating shaft has a groove that extends along said rotating shaft and receives said rotating shaft therein, and
a bottom of said groove has a cross section of a triangular shape in a direction crossing the extending direction of said rotating shaft.

7. A film deposition apparatus including the clamp member recited in claim 1.

8. A film deposition method, comprising the steps of:
holding a substrate using the clamp member recited in claim 1;
forming a film on a surface of said held substrate; and
separating said substrate from said holding portion of said clamp member after completion of said step of forming a film, by pressing said other end of said rotating member of said clamp member against said holding portion to rotate said rotating member about said rotating shaft, to thereby cause said one end of said rotating member to press a part of said substrate.

9. A manufacturing method of a semiconductor device using the film deposition method recited in claim 8, wherein
said substrate is a semiconductor substrate, and
in said step of forming a film, sputtering is used to form said film.
